(19) United States
(12) Patent Application Publication
(10) Pub. No.: US 2005/0133913 A1
(43) Pub. Date: Jun. 23, 2005

(54) Stress distribution package

(76) Inventor: Dan Okamoto, Oita (JP)

Correspondence Address: TEXAS INSTRUMENTS INCORPORATED, P O BOX 655474, M/S 3999, DALLAS, TX, 75265, US

(21) Appl. No.: 10/738,174

(22) Filed: Dec. 17, 2003

(51) Int. Cl. H01L 21/48; H01L 23/52

(52) U.S. Cl. 257/737; 257/676; 438/123; 438/613; 257/786; 438/612

(57) ABSTRACT

A semiconductor device includes a package material that can be effective to mitigate damage caused by mechanical stress to the semiconductor device. The package material can cover and protect a semiconductor chip that can be included in the semiconductor device. The package material can include at least one groove effective to distribute mechanical stress within the semiconductor device.

### TECHNICAL FIELD

The present invention relates to integrated circuit packages and, more particularly, to a ball grid array package and to a method of manufacturing a ball grid array package.

### BACKGROUND OF THE INVENTION

Integrated circuits are usually formed on semiconductor wafers. The wafers are separated into individual chips and the individual chips are then handled and packaged. The packaging can be relevant to an integrated circuit fabrication process, both from the point of view of cost and of reliability. Specifically, the packaging cost can easily exceed the cost of the integrated circuit chip and the majority of device failures are generally packaging related.

The integrated circuit should be packaged in a suitable medium that will protect it in subsequent manufacturing steps and from the environment of its intended application. Wire bonding and encapsulation are the two main steps in the packaging process. Wire bonding connects the leads from the chip to the terminals of the package. The terminals allow the integrated circuit package to be connected to other components. Following wire bonding, encapsulation is employed to seal the surfaces from moisture and contamination and to protect the wire bonding and other components from corrosion and mechanical shock.

The packaging of integrated circuits has typically involved attaching an individual chip to a lead frame, where, following wire bonding and encapsulation, designated parts of the lead frame become the terminals of the package. The packaging of integrated circuits has also involved the placement of chips on a surface where, following adhesion of the chip to the surface and wire bonding, an encapsulant is placed over the chip to seal and protect the chip and other components.

One known type of package is a ball grid array (BGA) package. A BGA package can include a die or chip, multiple substrate layers, and a heat spreader/stiffener. The die can be mounted on the heat spreader/stiffener using a thermally conductive adhesive or glue, such as an epoxy. One of the substrate layers includes a signal plane that provides various signal lines or traces that can be coupled to a corresponding die bond pad using a wire bond. The signal traces are then coupled with a solder ball at the other end. As a result, an array of solder balls is formed so that the BGA package may be electrically and mechanically coupled to other circuitry, generally through a printed circuit board (PCB).

### SUMMARY OF THE INVENTION

The present invention relates to a semiconductor device that employs a package material that is effective to mitigate damage to the semiconductor device caused by mechanical stress to the semiconductor device. The semiconductor device includes a substrate and a semiconductor chip. The substrate has a first surface and an opposite second surface. The semiconductor chip has a third surface and an opposite fourth surface attached to the first surface of the substrate. A plurality of solder contacts can be formed on a periphery of the second surface of the substrate. A package material having a top surface and a bottom surface covers the third surface of the semiconductor chip. The top surface of the package material can include at least one groove effective to mitigate damage to the semiconductor device caused by mechanical stress to the semiconductor device. The at least one groove can form a groove pattern that can distribute mechanical stress within the semiconductor device.

In another aspect of the invention, a method is provided for fabricating a package material of a semiconductor device that is effective to mitigate damage to the semiconductor device caused by mechanical stress to the semiconductor device. The method includes providing a ball grid array (BGA) package that includes a semiconductor chip and a substrate. The substrate includes a first surface and an opposite second surface. The semiconductor chip can be attached to the first surface, and a plurality of solder contacts can be provided on the second surface of the substrate. A package material having a top surface and a bottom surface can cover the semiconductor chip and a portion of the substrate. The method further includes forming at least one groove in the top surface of package material to distribute mechanical stress within the semiconductor device.

### BRIEF DESCRIPTION OF THE DRAWINGS

The foregoing and other aspects of the present invention will become apparent to those skilled in the art to which the present invention relates upon reading the following description with reference to the accompanying drawings.

FIG. 1 illustrates a schematic cross-sectional view of a portion of a semiconductor device in accordance with an aspect of the present invention.

FIG. 2 illustrates a bottom plan view of the semiconductor device of FIG. 1.

FIG. 3 illustrates a schematic cross-sectional view of the semiconductor device of FIG. 1 coupled to a circuit board.

FIG. 4 illustrates a top plan view of the semiconductor device of FIG. 1 with a first groove pattern in accordance with the present invention.

FIG. 5 illustrates a top plan view of the semiconductor device of FIG. 1 with a second groove pattern in accordance with the present invention.

FIG. 6 illustrates a top plan view of the semiconductor device of FIG. 1 with a third groove pattern in accordance with the present invention.

FIG. 7 illustrates a top plan view of the semiconductor device of FIG. 1 with a fourth groove pattern in accordance with the present invention.

FIG. 8 illustrates a schematic cross-sectional view of a portion of the semiconductor device in accordance with another aspect of the invention.

FIG. 9 illustrates a schematic cross-sectional view of the semiconductor device of FIG. 8 coupled to circuit board.

FIG. 10 illustrates a methodology of fabricating a semiconductor device in accordance with an aspect of the invention.

### DETAILED DESCRIPTION

The present invention relates to a semiconductor device that includes a ball grid array (BGA) package. The BGA package employs a package material that can be effective to mitigate damage caused by mechanical stress to the semiconductor device. The package material can cover and protect a semiconductor chip that can be included in the semiconductor device. The package material can include a top surface and a bottom surface. The top surface of the package material can include at least one groove effective to mitigate damage to the semiconductor device, which results from a detrimental increase in mechanical stress within semiconductor device. The mechanical stress can be caused by deformation of the semiconductor device and/or impact of the semiconductor device. The impact and/or deformation can occur during subsequent packaging operations and/or normal customer use. The at least one groove can form a groove pattern that can distribute mechanical stress within the semiconductor device.

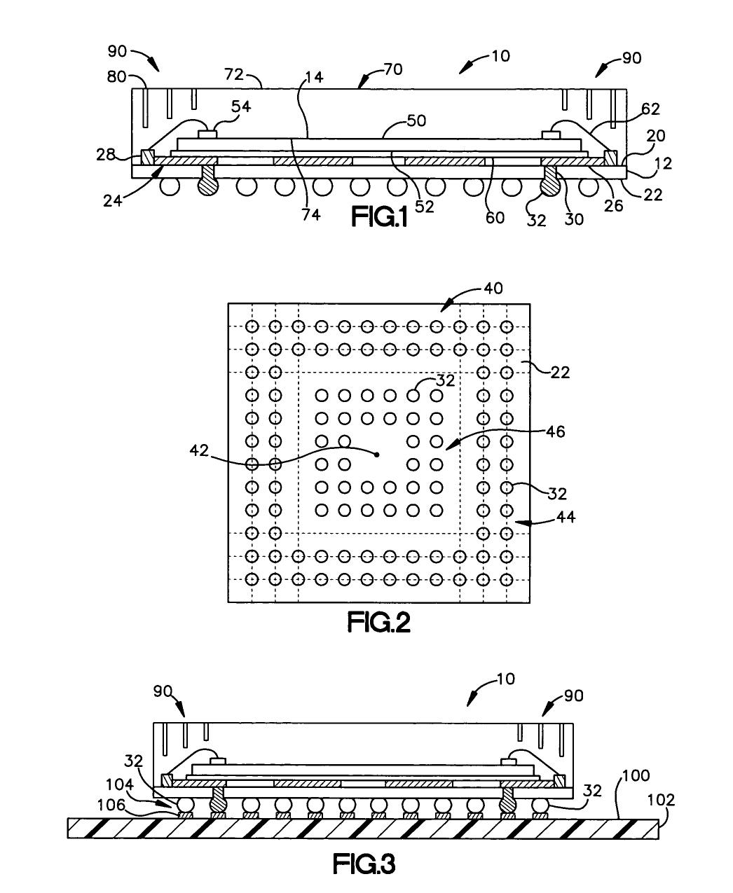

FIG. 1 is a cross-sectional view of a semiconductor device 10 comprising a ball grid array (BGA) package. The semiconductor device 10 includes a package substrate 12 and a semiconductor chip 14 that is attached to the package substrate 12. The package substrate 12 can comprise an electrically insulative material, such as a flexible dielectric tape. The flexible dielectric tape can include a thermally stable polymer, such as a normal chain non-thermoplastic polyimide with a thickness in the range, for example, of about 15 μm to about 75 μm. It will be appreciated by one skilled in the art that other types of substrates can be used. For example, the substrate may be a rigid laminate comprising a bismaleimide-triazine resin (BT-resin), flame retardant fiberglass composite substrate board (e.g., FR-4), and/or a ceramic substrate material.

The package substrate 12 includes a first surface 20 for mounting the semiconductor chip 14 and a second surface 22. The substrate 12 can be generally planar shaped and flat, such that the first surface 20 faces in an opposite direction with respect to the second surface 22. The package substrate 12, however, can have other shapes. The package substrate 12 can also be a chip-scale package having dimensions, for example, within about 1.2 times the size of the semiconductor chip 14.

The package substrate 12 can include a conductive pattern 24 (e.g., copper pattern) comprising a plurality of conductive traces 26 and conductive terminals 28 that are formed on the chip mounting surface 20 (i.e., the first surface) of the package substrate 12. The conductive pattern 24 can be formed, for example, by etching a metal foil that can be formed over the mounting surface 20 of the package substrate 12. The metal foil can have a thickness, for example, between about 15 μm and about 40 μm. Examples of foil materials that can be used include copper, copper alloy, gold, silver, palladium, platinum, and stacked layers of nickel/gold and nickel/palladium. It will be appreciated that there may be other conductive traces within the package substrate 12. For example, the package substrate 12 may have multiple layers with conductive traces on multiple levels.

The conductive traces 26 of the conductive pattern 24 are electrically coupled to conductive vias 30. The conductive vias 30 (i.e., through-holes filled with a conductive material) extend through the package substrate 12 to an array of generally ball shaped solder contacts 32 (e.g., solder balls) that are formed on the second surface 22 of the substrate 12. The solder contacts 32 can be used to form solder joints (FIG. 3) between the BGA package 10 and a circuit board (e.g., printed circuit board (PCB)) or an alternate level of interconnection.

The term solder balls used herein does not imply that the solder contacts are necessarily spherical. The solder contacts can have various forms, such as semispherical, half-dome, or truncated cone. The exact shape can be a function of the deposition technique (e.g., evaporation, plating, or prefabricated units) and reflow technique (e.g., infrared or radiant heat), and the material composition. The solder contacts are usually small in diameter (e.g., about 0.1 mm to about 0.3 mm). Several measures can be used to achieve consistency of geometrical shape of the solder contacts 32 by controlling the amount of material and uniformity of the reflow temperature. The materials used to form the solder contacts 32 can include alloys of lead, tin, and sometimes indium or silver. It will be appreciated that other materials can also be used. Dependent on the composition, the reflow temperature can be in the range from about 150° C. to about 260° C.

The solder contacts 32 can be connected to the vias 30 using a solder paste and/or a flux material (not shown). The solder paste can be screened around and into the vias on the second surface 22, and the solder contacts 32 can then be formed on the vias 30. In alternative example, the solder contacts 32 can be connected to the vias 30 by providing an array of solderizeable metal lands (not shown) at the terminus of the vias on the second surface 22 to which the solder contacts 32 can be formed.

The solder contacts 32 can be arrayed on the exposed second surface 22 in a pattern consistent with industry standards. For example, FIG. 2 illustrates that the solder contacts 32 can be arrayed in a concentric pattern 40 relative to a center point 42 on the second surface 22. The concentric pattern 40 can comprise an outer square array 44 of solder contacts 32, arranged about the perimeter of the second surface 22, and an inner square array 46, arranged at the center of the second surface 22. The area of the outer square array 44 can have dimensions, for example, of about 10 mm by 10 mm, and the area of the inner square array 46 can have dimensions, for example, of about 3 mm by about 3 mm. It will be appreciated that the solder contacts 32 can be provided on the second surface 22 in single array or in a plurality of arrays and that the area of the arrays can have dimensions, for example, between about 3 mm by about 3 mm and about 23 mm by about 23 mm.

Referring to FIG. 1, the semiconductor chip 14, which is attached to the first surface 20 of the package substrate 12, can have an active surface 50 (i.e., third surface) and a passive surface 50 (i.e., fourth surface). The active surface 50 can comprise one or more integrated circuits (not shown) and a plurality of conductive pads 54. The conductive pads 54 can be arranged about the periphery of the active surface 50 and provide electrical connecting points between the integrated circuits of the semiconductor chip 14 and the conductive terminals 28 on the package substrate 12. The semiconductor chip 14 can be formed from a semiconductor material, such as silicon, silicon germanium, gallium arsenide, or any other semiconductor material used in electronic device production. The thickness of the semiconductor chip 14 can be, for example, between about 200 microns and about 1000 microns. The integrated circuit can include product families, such as dynamic random access memory (DRAM), synchronous DRAM (SDRAM), static random access memories (SRAM), erasable programmable read memories (EPROM), logic circuits (LOGIC) digital signal processors (DSP), application-specific integrated circuits (ASIC), as well as other types of integrated circuit components.

The passive surface 52 of the semiconductor chip 14 is attached to the package substrate 14 with a die attaching material 60. The die attaching material 60 can include an epoxy, such as a conductive epoxy (e.g., silver filled epoxy or a silver filled glass epoxy). The semiconductor chip 14 can cover a substantial portion of the conductive pattern 24 formed on the mounting surface package 20 of the substrate 12. Conductive wires 62 can extend from the conductive pads 54 to the conductive terminals 28 of the conductive pattern 24. The conductive wires 62 can have a width, for example, of about 15 μm to about 32 μm and can comprise metals, such as gold, gold-beryllium alloy, copper, and aluminum.

A package material 70 encapsulates and protects the conductive wires 62 and the active surface 50 of the semiconductor chip 14 from damage and environmental influences. The package material 70 can also electrically insulates the semiconductor chip 14 from electrical components external the semiconductor device. The package material 70 can have a thickness, for example, of about 650 microns to about 800 microns and can form the shape of an upper portion of the semiconductor device 10. The package material 70 can comprise an electrically insulative molding compound, such as an epoxy based material used in transfer molding, as well as potting materials, such as cyanate ester-type resins, epoxies, polyesters, polyimides, and cyanocrylates. The package material 70 can be strengthened by organic as well as inorganic fillers. It will be appreciated that other package materials can also be used.

The package material 70 includes a top surface 72 and a bottom surface 74, substantially parallel with the top surface 72. The bottom surface 74 of the package material covers the active surface 50 of the semiconductor chip 14 and a substantial portion of the mounting surface 20 of the package substrate 12. The package material 70 also includes at least one groove 80 formed in the top surface of the package material 70 that allows the package material 70 to mitigate damage to the semiconductor device 10. The at least one groove 80 can allow the package material 70 to more readily deform upon the application of mechanical stress applied to the semiconductor device 10 during fabrication process as well as during packaging so that damage to the semiconductor device 10 can be mitigated.

The groove 80 can be formed in the package material 70, for example, by sawing (e.g., circular saw) or etching (e.g., wet or dry chemical etching) the top surface 22 of the package material 70. The groove 80 can transverse at least a portion of the top surface 70 of the package material and can extend substantially perpendicular to the top surface 20. Alternatively, the groove 80 can extend within package material 70 at angle that is not substantially perpendicular to the top surface 72. The sidewall profile of the groove 80, although illustrated as being substantially rectangular, can be toroidal, semicircular, or vee shaped, depending on the method used to form the groove 80. The groove 80 can have a depth, for example, of about 50 μm to about 200 μm and a width, for example, of about 200 microns to about 400 microns. The depth and width of the at least groove can depend on the thickness of the package material 70 as well as the area of the package material 70.

A plurality of grooves 80 can be provided in the package material 70. The grooves 80 can be spaced apart laterally along the top surface 72 and be aligned over the package substrate as well as over the semiconductor chip 14. The at least one groove 80 and/or the plurality of grooves 80 can be arranged in the package material 70 in a groove pattern 90 that can be used distribute mechanical stress within the semiconductor device, and particularly distribute stress on the solder joints (FIG. 3). For example, FIG. 3 illustrates the semiconductor device 10 of FIG. 1 mounted onto a surface 102 of a circuit board 102 (e.g., a module board consisting of a memory module) so that the solder contacts form solder joints with conductive pads 106 of the circuit board 102. The reliability of the solder joints 104 can be affected by the ability of the semiconductor device 10 to distribute mechanical stress between the solder joints 106 upon deformation of the semiconductor device 10 and/or the circuit board 102. Mechanical stress resulting from a deformation, such as impact effective to the cause the semiconductor device and the circuit board to deform (e.g., impact of a semiconductor device with a floor as a result of dropping the semiconductor device), can concentrate at solder contact joints 106 coincident and/or remote from the point of deformation and/or impact. The groove pattern 90 in the top surface 72 of the package material 170 can allow the package material 70 to more readily deform and distribute the mechanical stress on the solder joints 104. It will be appreciated that the groove pattern 90 can also distribute mechanical stress applied to the semiconductor device by other sources, such as mechanical stress induced during post fabrication processing as well as mechanical stress resulting from shipping and normal customer use of the semiconductor device 10.

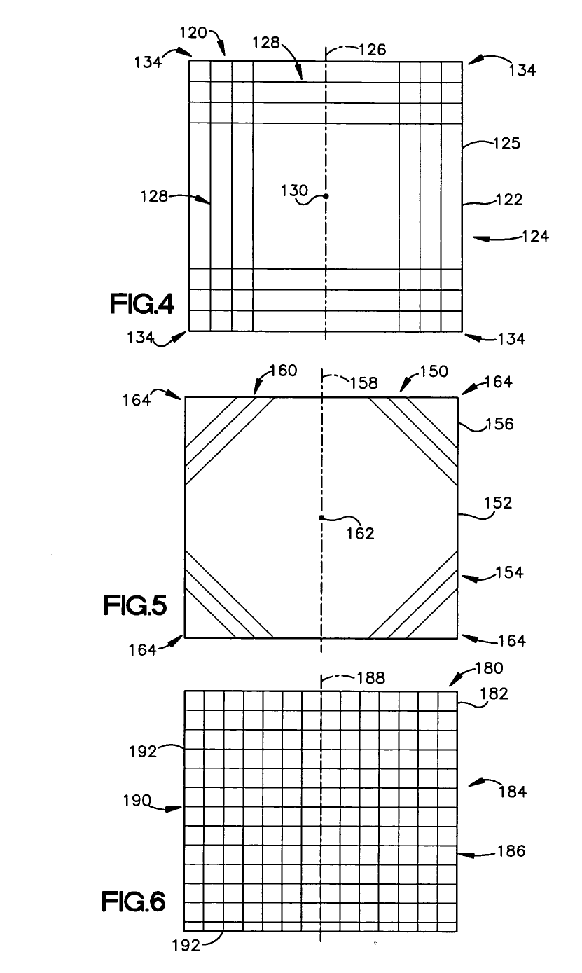

FIG. 4 is a top plan view illustrating an exemplary embodiment of a groove pattern 120 formed in a package material 122 of a semiconductor device 124. The package material has a substantially rectangular shaped top surface 125 that extends along an axis 126. The groove pattern 120 includes rows of grooves 128 that extend parallel and perpendicular relative to the axis 126. The rows of grooves 128 are concentrically arranged relative to a center 130 of the top surface 125 of the package material 122. The rows of grooves 128 also extend substantially parallel to each side of the package material so that two perpendicular rows of grooves intersect at corner positions of the package material 122. The groove pattern 120 can be formed in the top surface 125 of the package material 122 using a saw or etching process. Each groove 128 can have the substantially same depth and same width. It will be appreciated though that the depth and width of the grooves can vary from groove to groove. The groove pattern 120 partitions the package material 124 so that mechanical stress at the periphery of the semiconductor device can be distributed at the solder joints (not shown) along the periphery of the semiconductor device 122.

FIG. 5 is a top plan view illustrating another example of a groove pattern 150 that can be formed in a package material 152 of a semiconductor device 154. The package material 152 in accordance with this example has a substantially rectangular shaped top surface 156 that extends along an axis 158. The groove pattern 150 includes rows of grooves 160 that extend at angles substantially greater than 90° or substantially smaller than 90° relative to the axis 158. The rows of grooves 150 are concentrically arranged relative to a center 162 of the top surface 156 of the package material 152. The rows of grooves 160 also extend across separate corners 164 so that none of the rows of grooves 160 intersect. The groove pattern 150 can be formed in the top surface 156 of the package material 152 using a saw or etching process. Each groove can have the substantially same depth and same width. It will be appreciated though that the depth and width of the grooves can vary from groove to groove. The groove pattern 150 partitions the package material 152 so that mechanical stress at the corners of the semiconductor device 154 can be distributed at the solder joints (not shown) along the corners of the semiconductor device 154.

FIG. 6 is a top plan view illustrating yet another example a groove pattern 180 formed in a package material 182 of a semiconductor device 184. The package material 182 in accordance with this example has a substantially rectangular shaped top surface 186 that extends along an axis 188. The groove pattern includes a grid (or cross-hatch) 190 of substantially intersecting grooves 192 that extend substantially parallel and substantially perpendicular relative to the axis 188. The grooves 192 define a substantially checker board groove pattern 180 across the top surface 186 of the package material 182. The groove pattern 180 can be formed in the top surface 186 of the package material 182 using a saw or etching process. Each groove 192 can have the substantially same depth and same width. It will be appreciated though that the depth and width of the grooves 192 can vary from groove to groove. The groove pattern 180 partitions the package material so that mechanical stress within the semiconductor device 184 can be distributed across the solder joints (not shown) of the semiconductor device 184.

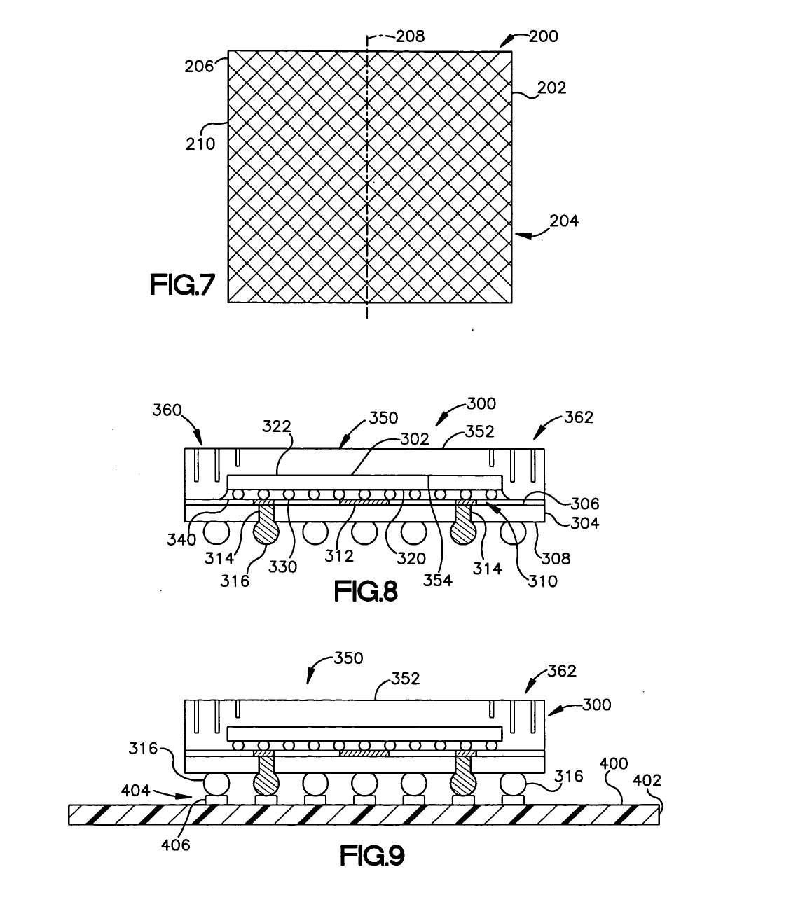

FIG. 7 is a top plan view of still another example of a groove pattern 200 that can be formed in a package material 202 of a semiconductor device 204. The package material 202 in accordance with this example has a substantially rectangular shaped top surface 206 that extends along an axis 208. The groove pattern 200 includes a grid 210 (or cross-hatch) of substantially intersecting grooves 212 that extend substantially at angles substantially greater than 9020 and substantially less than 90° relative to the axis 208. The grooves 212 define a substantially checker board groove pattern across the top surface 206 of the package material 202. The groove pattern 200 can be formed in the top surface of the package material 204 using a saw or etching process. Each groove 212 can have the substantially same depth and same width. It will be appreciated though that the depth and width of the grooves 212 can vary from groove to groove. The groove pattern 200 partitions the package material 204 so that mechanical stress on the semiconductor device can be distributed across the solder joints (not shown) of the semiconductor device.

It will be appreciated by one skilled in the art that yet other groove patterns can be formed in the top surface of the package material. These other groove patterns can be effective to distribute the mechanical stress on the solder joints. It will be appreciated that these other groove patterns can also distribute stress on other portion of the semiconductor device, such as the semiconductor chip or the package substrate.

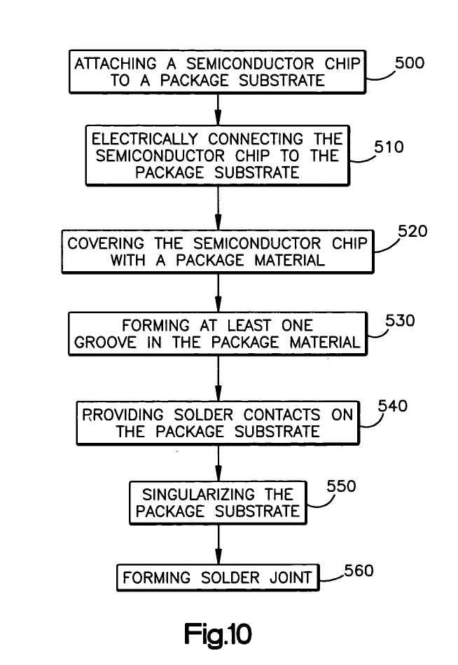

FIG. 8 illustrates another example of a semiconductor device 300 comprising a ball grid array package in accordance with the present invention. In this example, the semiconductor device 300 includes a semiconductor chip 302 that can be attached to a package substrate 304 in a flip chip type arrangement instead the wire bonding arrangement, as illustrated and described above with respect to FIG. 1. The package substrate 304 can comprise an electrically insulative material, such as a flexible dielectric tape. It will be appreciated by one skilled in the art that other types of substrates can be used. For example, the substrate may be a rigid laminate comprising a bismaleimide-triazine resin (BT-resin), flame retardant fiberglass composite substrate board (e.g., FR-4), and/or a ceramic substrate material.

The package substrate 304 includes a first surface 306 for mounting the semiconductor chip 302 and a second surface 308. The package substrate 304 can be generally planar shaped and flat, such that the first surface faces 306 in an opposite direction with respect to the second surface 308. The package substrate 304 can have other shapes. The package substrate 304 can also be a chip-scale package (e.g., having dimensions within about 1.2 times the size of the semiconductor chip).

The package substrate 304 can include a conductive pattern 310 (e.g., copper pattern) comprising a plurality of conductive traces 312 that are formed on the chip mounting surface 306 (i.e., the first surface) of the package substrate 304. The conductive pattern 310 can be formed, for example, by etching a metal foil that is formed over the mounting surface 306 of the package substrate 304. The metal foil can have a thickness, for example, between about 15 microns and 40 microns. It will be appreciated that there may be other traces within the package substrate 304. For example, the package substrate 304 may have multiple layers with traces on multiple levels.

The conductive traces 312 of the conductive pattern are electrically coupled to conductive vias 314. The conductive vias 314 extend through the package substrate 304 to an array of generally ball shaped solder contacts 316 (e.g., solder balls) that are formed on the second surface 308 of the package substrate 304. The solder contacts 316 can be connected to the vias 314 using a solder paste and/or a flux material. Alternatively, the solder contacts 316 can be connected to the vias 314 by providing an array of solderizeable metal lands at the terminus of the vias 314 on the second surface to which the solder balls can be attached.

The solder contacts 316 can be arrayed on the exposed second surface in a pattern consistent with industry standards. For example, the solder contacts 316 can be arrayed in a concentric pattern (not shown) relative to a center point on the bottom surface. It will be appreciated that the solder contacts 316 can be provided on the second surface in single array or in a plurality of arrays and that the area of the arrays can have dimensions, for example, between about 3 mm by about 3 mm and about 23 mm by about 23 mm.

The semiconductor chip 302, which is attached to the substrate 304, can have an active surface 320 and a passive surface 322. The active surface 320 can comprise a plurality of integrated circuits (not shown) and a plurality of conductive bump contacts 330. The bump contacts 330 are preferably eutectic solder balls. Alternatively, conductive polymeric bumps, lead free bumps, or other preformed spheres of readily solderable material can be used to form the contact 330. The bump contacts 330 can be arrayed on the active surface 320 of the semiconductor chip 302 in a manner, which minimizes on-chip bussing, and consequently reduces resistivity of interconnection circuits. Alternatively, the bump contacts 330 can be positioned near the chip perimeter or in the center of the semiconductor chip 302.

The bump contacts 330 are used to couple the active surface 320 of the semiconductor chip 302 to the package substrate 304. The semiconductor chip 302 can cover a substantial portion of the conductive pattern 310 formed on the mounting surface 306 of the package substrate 304. The bump contacts 330 can be electrically connected to the conductive traces 312 of the conductive pattern 310. An underfill material 340 can be disposed between the semiconductor chip 302 and the package substrate 304, and surround the solder bumps 330.

A package material 350 encapsulates and protects the semiconductor chip 302 from damage and environmental influences. The package material 350 can have a thickness, for example, of about 650 microns to about 800 microns and can form the shape of an upper portion of the semiconductor device 300. The package material 350 can comprise a molding compound, such as an epoxy based material used in transfer molding, as well as potting materials, such as cyanate ester-type resins, epoxies, polyesters, polyimides, and cyanocrylates. The package material 350 can be strengthened by organic as well as inorganic fillers. It will be appreciated that other package materials 350 can also be used.

The package material 350 includes a top surface 352 and a bottom surface 354, substantially parallel with the top surface 352. The bottom surface 354 of the package material 350 covers the passive surface 322 of the semiconductor chip 302 and a substantial portion of the mounting surface of the package substrate 304. The package material 350 also includes at least one groove 360 in the top surface 352 of the package material 350. The at least one groove 360 can allow the package material 350 to more readily deform upon the application of mechanical stress applied to the semiconductor device 300 during fabrication process as well as during packaging so that damage to the semiconductor device 300 can be mitigated.

The groove 360 can be formed in the package material 350, for example, by sawing (e.g., circular saw) or etching (e.g., wet or dry chemical etching) the top surface 352 of the package material. The groove 360 can transverse at least a portion of the top surface 352 of the package material 350 and can extend substantially perpendicular to the top surface 352. Alternatively, the groove 350 can extend within package material 350 at angle that is not substantially perpendicular to the top surface 352. The sidewall profile of the groove 360, although illustrated as being substantially rectangular, can be toroidal, semicircular, or vee shaped, depending on the method used to form the groove 360. The groove can have a depth, for example, of about 50 μm to about 200 μm and a width, for example, of about 200 μm to about 400 μm. The depth and width of the at least groove 360 can depend on the thickness of the package material 350 as well as the area of the package material 350.

A plurality of grooves 360 can be provided in the package material 350. The grooves 360 can be spaced apart laterally along the top surface 352 and be aligned over the substrate 304 as well as over the semiconductor chip 302. The at least one groove 350 and/or the plurality of grooves 360 can be arranged in the package material in a groove pattern 362 that can be used distribute mechanical stress within the semiconductor device, and particularly distribute mechanical stress on the solder joints (FIG. 9). For example, FIG. 9 illustrates the semiconductor device 300 mounted onto a surface 400 of a circuit board 402 (e.g., a module board consisting of a memory module) so that the solder contacts 316 form solder joints 404 with conductive pads 406 of the circuit board 402. The reliability of the solder joint 404 can be affected by the ability of the semiconductor device 300 to distribute mechanical stress between the solder joints 404 upon deformation of the semiconductor device 300 and the circuit board 402. Mechanical stress resulting from a deformation, such as impact effective to the cause the semiconductor device 300 and circuit board 402 to deform (e.g., impact of a semiconductor device with a floor as a result of dropping the semiconductor device), can concentrate at solder joints 404 coincident and/or remote from the point of deformation and/or impact. The groove pattern 362 in the top surface 352 of the package material 350 can allow the package material 350 to more readily deform and distribute the mechanical stress on the solder joints 404. It will be appreciated that the groove pattern 360 can also distribute mechanical stress applied to the semiconductor device 300 by other sources, such as mechanical stress induced in during post fabrication processing as well as mechanical stress resulting from shipping and normal customer use of the semiconductor device.

Those skilled in the art will also understand and appreciate variations in the semiconductor device in accordance with the invention. For example, it is to be appreciated that a plurality of ball grid array packages can be formed on a sheet of insulative material. Moreover, it is to be appreciated that grooves can be aligned over the solder contacts to more readily distribute mechanical stress on the solder ball joints.

FIG. 10 illustrates a methodology of fabricating a semiconductor device that includes a package material, which is effective to mitigate damage to the semiconductor device caused by mechanical stress to the semiconductor device. The methodology begins at 500 such as in connection with attaching a semiconductor chip to a package substrate that is formed from a portion of a sheet of insulative material, such as a flexible dielectric tape or a rigid laminate. The semiconductor chip can comprise an active surface and a passive surface. The active surface can include a plurality of integrated circuits and a plurality of conductive pads. The package substrate has a mounting surface for receiving the semiconductor chip and an opposite solder contact surface on which a plurality of solder contacts can be arrayed. The semiconductor chip can be attached to the mounting surface of the package substrate using a die attach material or a plurality of solder contacts. Where a die attach material is used, the passive surface of the semiconductor chip can be attached to the mounting surface of the package substrate. Where solder contacts are used, the active surface of the semiconductor chip can be attached to the mounting surface of the package substrate.

At 510, the semiconductor chip is electrically connected to the package substrate. The semiconductor chip can be electrically connected to the package substrate, for example, by wire bonding the conductive pads on the semiconductor chip to conductive terminals on the package substrate. In another example, the semiconductor chip can be electrically to the package substrate by solder contacts used to attach the semiconductor chip to the package substrate.

At 520, the semiconductor chip is covered with a package material that protects the semiconductor chip from damage and environmental influences. The package material can comprise a molding compound, such as an epoxy-based material used in transfer molding. The package material can include a top surface and a bottom surface that covers the semiconductor chip and a portion of the mounting surface of the package substrate.

At 530, at least one groove is formed in the package material that allows the package material to more readily deform upon application of mechanical stress applied to the semiconductor device. The groove can be formed in the semiconductor device by sawing the package material. Alternatively, the groove can be formed in the semiconductor device by etching the package material. The depth and width of the groove can depend on the thickness of the package material as well as the width of the package material. The at least one groove can be formed in the semiconductor device in groove pattern that can distribute mechanical stress within the semiconductor device.

At 540, solder contacts are arrayed on the solder contact surface of the package substrate following formation of the at least one groove in the package material. The contacts can be arrayed on the solder contact surface, for example, by screening flux or solder paste around and into the termini of vias on the solder contact surface and attaching solder balls to the termini of the vias.

At 550, the package substrate is separated (i.e., singularized) from the sheet of insulative material. The package substrate can be separated from the sheet of insulative material by mechanically sawing or other singulation procedures through a periphery of the portion of the sheet of insulative material that defines the package substrate. Package material formed over the periphery of the portion of the sheet of insulative material that defines the package substrate can also be sawed to separate the package substrate. The separated package substrate with the overlying semiconductor chip and package material and the underlying solder contacts form a ball grid array package in accordance with an aspect of the invention.

At 560, the package substrate can be attached to a mounting surface of a circuit board so that the solder contacts form solder joints with conductive pads on the circuit board. The groove pattern can allows the package material to distribute mechanical stress on the solder joints during deformation of the semiconductor device.

What has been described above includes examples and implementations of the present invention. Because it is not possible to describe every conceivable combination of components, circuitry or methodologies for purposes of describing the present invention, one of ordinary skill in the art will recognize that many further combinations and permutations of the present invention are possible. Accordingly, the present invention is intended to embrace all such alterations, modifications and variations that fall within the spirit and scope of the appended claims.

1. A semiconductor device comprising:
a substrate have a first surface and an opposite second surface;
a plurality of solder contacts formed on the second surface of the substrate;
a semiconductor chip coupled to the first surface of the substrate; and
a package material covering the semiconductor chip, the package material including a surface spaced apart from the second surface with at least one groove effective to distribute mechanical stress during deformation of the semiconductor device.

2. The semiconductor device of claim 1, the at least one groove forming a groove pattern in the surface of the package material, the groove pattern partitioning the package material so that mechanical stress on the periphery of the semiconductor device can be distributed across the semiconductor device.

3. The semiconductor device of claim 2, the groove pattern including rows of grooves that are concentrically arranged relative to a center of the surface of the package material.

4. The semiconductor device of claim 3, the surface of the package material being substantially rectangular and the groove pattern including at least two rows of grooves that that intersect near corner positions of the surface the package material.

5. The semiconductor device of claim 3, the surface of the package material being substantially rectangular and the groove pattern including rows of grooves that extend across separate corners of the surface of the package material.

6. The semiconductor device of claim 2, the groove pattern comprising a plurality of substantially intersecting grooves arranged in a grid pattern, the groove pattern extending across the surface of the package material.

7. The semiconductor device of claim 1, the at least one groove being formed in the surface of the package material by sawing the package material.

8. The semiconductor device of claim 1, further comprising a circuit board having a mounting surface, the plurality of solder contacts forming solder joints with the mounting surface to interconnect the second surface of substrate and the mounting surface of the circuit board, the at least one groove being effective to distribute mechanical stress at the solder joints during deformation of the semiconductor device.

9. A semiconductor device comprising:
a substrate having a first surface and an opposite second surface;
a circuit board having a mounting surface;
a plurality of solder joints interconnecting the second surface of substrate and the mounting surface of the circuit board; and
a package material having a top surface and a bottom surface, the bottom surface of the package material covering the first surface of the substrate, the top surface including at least one groove effective to distribute mechanical stress at the solder joints during deformation of the semiconductor device.

10. The semiconductor device of claim 9, the at least one groove further comprising a plurality of grooves arranged in a groove pattern in the top surface of the package material, the groove pattern partitioning the package material so that mechanical stress on the solder joints at a periphery of the semiconductor device can be distributed across the semiconductor device.

11. The semiconductor device of claim 9, the groove pattern including rows of grooves that are concentrically arranged relative to a center of the top surface of the package material.

12. The semiconductor device of claim 11, the top surface of the package material being substantially rectangular and the groove pattern including at least two rows of grooves that that intersect near corner positions of the top surface the package material.

13. The semiconductor device of claim 11, the top surface of the package material being substantially rectangular and the groove pattern including rows of grooves that extend across separate corners of the top surface of the package material.

14. The semiconductor device of claim 2, the groove pattern comprising a grid of substantially intersecting grooves, the groove pattern extending across the top surface of the package material.

15. The semiconductor device of claim 1, the at least one groove being formed in the top surface of the package material by sawing the package material.

16. A method of fabricating a semiconductor device, comprising:
providing a substrate including a first surface and an opposite second surface
attaching a semiconductor chip to the first surface, and a plurality of solder contacts to the second surface of the substrate;
covering the first surface of the semiconductor chip with a package material having a top surface and a bottom surface; and
forming at least one groove in the top surface of package material to distribute mechanical stress within the semiconductor device.

17. The method of claim 16, the formation of the at least one groove further comprising forming a groove pattern in the top surface of the package material to partition the package material so that mechanical stress on the periphery of the semiconductor device can be distributed across the semiconductor device.

18. The method of claim 16, further comprising:
interconnecting the plurality of solder contacts with a mounting surface of a circuit board to form a plurality of solder joints, the at least one groove being effective to distribute mechanical stress on the solder joints during deformation of the semiconductor device.

20. The method of claim 19, the at least one groove forming a groove pattern in the top surface of the package material, the groove pattern partitioning the package material so that mechanical stress on the solder joints at a periphery of the semiconductor device can be distributed across the semiconductor device.
